(19) United States
(12) Patent Application Publication
(10) Pub. No.: US 2026/0271528 A1
(43) Pub. Date: Sep. 10, 2026

(54) DISPLAY SUBSTRATE AND DISPLAY APPARATUS

(71) Applicants: Beijing BOE Technology Development Co., Ltd., Beijing (CN); BOE Technology Group Co., Ltd., Beijing (CN)

(72) Inventors: Yue ZHANG, Beijing (CN); Juanjuan YOU, Beijing (CN); Cheng XU, Beijing (CN); Dandan ZHOU, Beijing (CN)

(21) Appl. No.: 18/993,530

(22) PCT Filed: May 16, 2024
(86) PCT No.: PCT/CN2024/093579

§ 371 Date: Jan. 11, 2025

(30) Foreign Application Priority Data
Jun. 25, 2023 (CN) 202310754037.2

(51) Int. Cl. H10K 59/122; H10K 59/124; H10K 59/80

(52) U.S. Cl. CPC H10K 59/122; H10K 59/124; H10K 59/879

(57) ABSTRACT

A display substrate and a display apparatus. The display substrate comprises a driving structure layer, a planarization layer and a light-emitting structure layer, which are sequentially stacked on a base in a direction away from the base, wherein the light-emitting structure layer comprises a plurality of light-emitting elements and a pixel definition layer that separates adjacent light-emitting elements, the pixel definition layer being provided with a plurality of pixel openings, and the light-emitting elements being arranged at the pixel openings; areas defined by the pixel openings are light-emitting areas, and areas outside the light-emitting areas are non-light-emitting areas; and in the non-light-emitting areas, the planarization layer or/and at least one insulating layer is/are provided with a light extraction structure, and the light extraction structure is configured to concentrate light emitted from the light-emitting elements in a direction perpendicular to the base.

### CROSS-REFERENCE TO RELATED APPLICATION

The present application is a U.S. National Phase Entry of International Application No. PCT/CN2024/093579 having an international filing date of May 16, 2024, which claims priority of Chinese Patent Application No. 202310754037.2, filed to the CNIPA on Jun. 25, 2023 and entitled “Display Substrate and Display Apparatus”. Contents of the above-identified applications are incorporated herein by reference.

### TECHNICAL FIELD

Embodiments of the present disclosure relate to, but are not limited to, the field of display, and particularly relate to a display substrate and a display apparatus.

### BACKGROUND

Organic light emitting diode (OLED) display products have gradually become the mainstream products in the field of display because they have advantages of self-illumination, a wide viewing angle, a high contrast ratio, low power consumption, an extremely high reaction speed, etc. At present, there are two technical routes for the production of OLED display panels. One technical route is that OLEDs with three primary colors of red, green and blue (RGB) emit light separately, which has the advantages of simple and mature process and easy operation. However, due to the need for fine-precision mask and precise alignment when preparing high-resolution display screens, the production capacity is low and the cost is high. Moreover, because there are large differences in the life, excitation rate and attenuation of RGB three primary-color OLEDs, it is easy to cause the color cast of OLED display panels. The other technical route is white light OLED+color film technology. This technology does not require mask alignment and usually adopts a bottom emission light emitting method, which greatly simplifies the evaporation process and can be used to prepare a large-sized high-resolution OLED display panel.

Among the light emitted by the OLED device of the OLED display substrate, the light with a large emission angle will be reflected back into the display substrate and cannot be emitted. Some techniques change the path of light to reduce the light confined in the display substrate by adding a light extraction layer, such as forming a concave-convex lens structure 2′ on the surface of the flat layer, then forming a concave-convex anode and light emitting layer above the flat layer. The light emitted by the OLED device 1′ undergoes multiple reflections through the concave-convex lens structure 2′, so that the light propagates at an angle smaller than the critical angle of total reflection between the base substrate (such as glass) 3′ of the display substrate and the air, to extract the light trapped in the display substrate. However, this design still causes a portion of the light (schematically shown by an dotted line with arrow in FIG. 1) having an emission angle greater than the critical angle of total reflection between the base substrate 3′ of the display substrate and the air. This portion of the light is totally reflected at the interface between the base substrate 3′ of the display substrate and the air and cannot be extracted, as shown in FIG. 1.

### SUMMARY

The following is a summary of subject matters described herein in detail. This summary is not intended to limit the protection scope of claims.

An embodiment of the present disclosure provides a display substrate including a display area, the display area including a driving structure layer, a flat layer, and a light emitting structure layer sequentially stacked on a base substrate in a direction away from the base substrate. The driving structure layer includes a plurality of pixel driving circuits which include a plurality of transistors. The driving structure layer includes a plurality of conductive structure layers and a plurality of insulating layers in a direction perpendicular to the base substrate. The conductive structure layers and the insulating layers are alternately disposed in a direction perpendicular to the base substrate. The light emitting structure layer includes a plurality of light emitting elements and a pixel definition layer that separates adjacent light emitting elements, the pixel definition layer is provided with a plurality of pixel openings, and the light emitting elements are disposed at the pixel openings. A region defined by the pixel openings is a light emitting region, and a region other than the light emitting region is a non-light emitting region. In the non-light emitting region, the flat layer or/and at least one of the insulating layers is provided with a light extraction structure, which is configured to gather light emitted from the light emitting elements in the direction perpendicular to the base substrate.

An embodiment of the present disclosure further provides a display apparatus including the display substrate described above.

Other aspects of the present disclosure may be comprehended after the drawings and the detailed descriptions are read and understood.

### BRIEF DESCRIPTION OF DRAWINGS

Accompanying drawings are intended to provide a further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of components in the drawings do not reflect actual scales, and are only intended to schematically illustrate contents of the present disclosure.

FIG. 1 is a schematic diagram of a partial cross-sectional structure of a display substrate according to some techniques;

FIG. 2 is a schematic diagram of a planar structure of a display substrate according to some exemplary embodiments;

FIG. 3 is a schematic diagram of a cross-sectional structure taken along A-A of FIG. 2 according to some exemplary embodiments;

FIG. 4 is a schematic diagram of a cross-sectional structure taken along A-A of FIG. 2 according to some other exemplary embodiments;

FIG. 5 is a schematic diagram of a cross-sectional structure taken along A-A of FIG. 2 according to some further exemplary embodiments;

FIG. 6 is a schematic diagram of a cross-sectional structure taken along A-A of FIG. 2 according to some further exemplary embodiments;

FIG. 7 is a schematic diagram of a cross-sectional structure taken along A-A of FIG. 2 according to some further exemplary embodiments; and

FIG. 8 is a schematic diagram of a cross-sectional structure taken along A-A of FIG. 2 according to some further exemplary embodiments.

### DETAILED DESCRIPTION

Those of ordinary skills in the art should understand that modifications or equivalent replacements may be made to the technical solutions of the embodiments of the present disclosure without departing from the spirit and scope of the technical solutions of the embodiments of the present disclosure, and should all fall within the scope of the claims of the present disclosure.

An embodiment of the present disclosure provides a display substrate including a display area, the display area including a driving structure layer, a flat layer, and a light emitting structure layer sequentially stacked on a base substrate in a direction away from the base substrate. The driving structure layer includes a plurality of pixel driving circuits which include a plurality of transistors. The driving structure layer includes a plurality of conductive structure layers and a plurality of insulating layers in a direction perpendicular to the base substrate. The conductive structure layers and the insulating layers are alternately disposed in a direction perpendicular to the base substrate. The light emitting structure layer includes a plurality of light emitting elements and a pixel definition layer that separates adjacent light emitting elements, the pixel definition layer is provided with a plurality of pixel openings, and the light emitting elements are disposed at the pixel openings. A region defined by the pixel openings is a light emitting region, and a region other than the light emitting region is a non-light emitting region. In the non-light emitting region, the flat layer or/and at least one of the insulating layers is provided with a light extraction structure, which is configured to gather light emitted from the light emitting elements in a direction perpendicular to the base substrate.

The display substrate according to the embodiment of the present disclosure can gather the light emitted from the light emitting elements in the direction perpendicular to the base substrate by providing the light extraction structure in the flat layer or/and at least one of the insulating layers in the non-light emitting region. In this way, a portion of the light that would originally undergo total reflection at an interface between the base substrate and the air and thus cannot be emitted can be extracted, increasing the efficiency of light extraction. Moreover, a large-angle light emitted originally at the interface between the base substrate and the air can be gathered in the direction perpendicular to the base substrate, making a light concentrating and improving light leakage phenomenon.

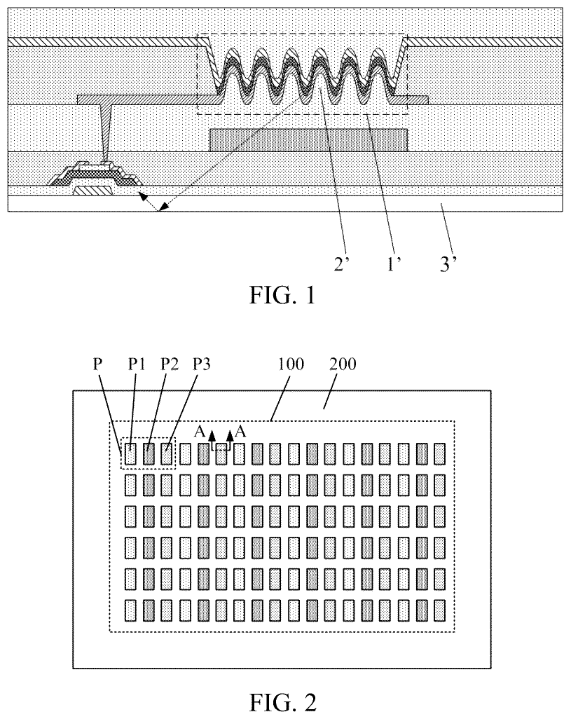

FIG. 2 is a schematic diagram of a planar structure of a display substrate according to some exemplary embodiments. As shown in FIG. 2, the display substrate includes a display area 100 and a non-display area 200 located at a periphery of the display area 100. The display area 100 includes a plurality of pixel units P arranged in an array on a base substrate, and the pixel units P include a plurality of sub-pixels that emit light of different colors. For example, the pixel unit P may include a first sub-pixel P1 emitting light of a first color (such as red light), a second sub-pixel P2 emitting light of a second color (such as green light), and a third sub-pixel P3 emitting light of a third color (such as blue light). One or two of the second sub-pixels P2 emitting light of a second color (such as green light) in the pixel unit P may be provided. In other embodiments, the pixel unit may further include a fourth sub-pixel that emits light of a fourth color (such as white light or yellow light). Embodiments of the present disclosure do not limit the type, number, and arrangement of sub-pixels included in a pixel unit.

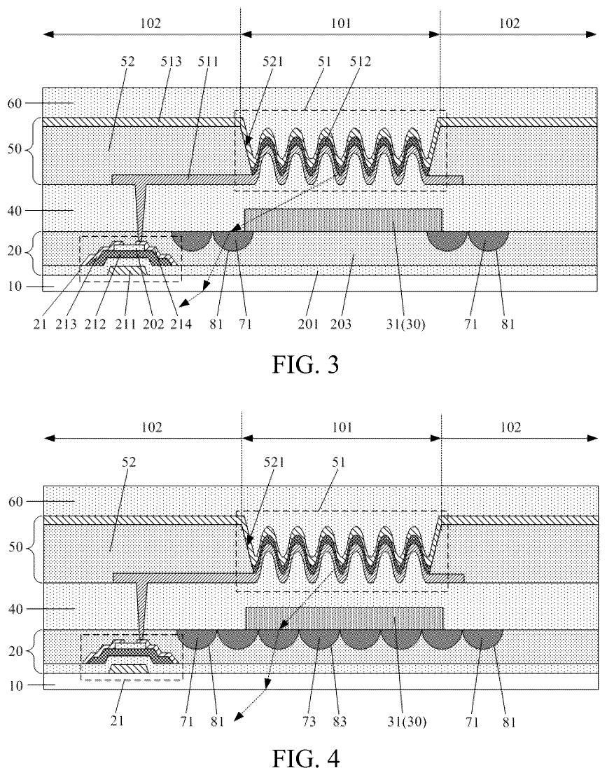

FIG. 3 is a schematic diagram of a cross-sectional structure taken along A-A of FIG. 2 according to some exemplary embodiments. As shown in FIGS. 2 and 3, the display substrate includes a display area 100 and a non-display area 200 located at a periphery of the display area 100. The display area 100 includes a driving structure layer 20, a flat layer 40, and a light emitting structure layer 50 which are sequentially stacked on the base substrate 10 in a direction away from the base substrate 10.

The driving structure layer 20 includes a plurality of pixel driving circuits including a plurality of transistors 21. The driving structure layer 20 includes a plurality of conductive structure layers and a plurality of insulating layers in a direction perpendicular to the base substrate 10, and the conductive structure layers and the insulating layers are alternately disposed in a direction perpendicular to the base substrate 10.

The light emitting structure layer 50 includes a plurality of light emitting elements 51, and a pixel definition layer 52 that separates adjacent light emitting elements 51. The pixel definition layer 52 is provided with a plurality of pixel openings 521 where the light emitting elements 51 are disposed. A region defined by the pixel openings 521 is a light emitting region 101, and a region other than the light emitting region 101 is a non-light emitting region 102. The light emitting element 51 is connected to the pixel driving circuit and emits light under the driving of the pixel driving circuit. Each sub-pixel includes the light emitting element 51.

In the non-light emitting region 102, an insulating layer in contact with the flat layer 40 among the plurality of insulating layers is provided with a first light extraction structure 71. The light extraction structure includes the first light extraction structure 71, which is configured to gather light emitted from the light emitting element 51 in a direction perpendicular to the base substrate 10.

In some exemplary embodiments, as shown in FIG. 3, the plurality of conductive structure layers of the driving structure layer 20 may include a first conductive structure layer, a second conductive structure layer, and a third conductive structure layer sequentially disposed in a direction away from the base substrate 10. The first conductive structure layer and the third conductive structure layer may be metal layers, and the second conductive structure layer may be a semiconductor layer. The first conductive structure layer may include a gate electrode 211 of the transistor 21, the second conductive structure layer may include an active layer 212 of the transistor 21, and the third conductive structure layer may include a source electrode 213 and a drain electrode 214 of the transistor 21. The plurality of insulating layers of the driving structure layer 20 may include a first insulating layer 201 between the first conductive structure layer and the second conductive structure layer, a second insulating layer 202 between the second conductive structure layer and the third conductive structure layer, and a third insulating layer 203 covering the third conductive structure layer.

The plurality of insulating layers of the driving structure layer 20 may all be inorganic insulating layers, and each insulating layer may be made of any one or more of silicon oxide (SiO_{X}), silicon nitride (SiN_{X}) and silicon oxynitride (SiO_{X}N_{Y}), which may be a single-layer structure or a multi-layer composite structure. The flat layer 40 may be an organic insulating layer, and may be made of a resin material. The conductive structure layer of a metal material of the driving structure layer 20 may be made of any one or more of Argentum (Ag), Copper (Cu), Aluminum (Al), and Molybdenum (Mo), or an alloy material of the above metals, such as an Aluminum Neodymium alloy (AINd) or a Molybdenum Niobium alloy (MoNb), and may be of a single-layer structure or a multi-layer composite structure, such as Mo/Cu/Mo. The active layer 212 may be made of materials such as amorphous indium gallium zinc oxide (a-IGZO), zinc oxynitride (ZnON), indium zinc tin oxide (IZTO), amorphous silicon (a-Si), polysilicon (p-Si), hexathiophene, or polythiophene, etc. That is, the present disclosure is applicable to transistors that are manufactured based on oxide technology, silicon technology and organic technology. The base substrate 10 may be made of a transparent material such as glass.

In FIG. 3, only one film layer structure of the driving structure layer is schematically illustrated, the transistor 21 in FIG. 3 is a bottom gate transistor, and FIG. 3 illustrates three conductive structure layers and three insulating layers. In another embodiment, the transistor 21 may be a top gate transistor, and in the driving structure layer 20, the number of conductive structure layers may three or more, and the number of insulating layers may be three or more. Further, the plurality of insulating layers of the driving structure layer 20 illustrated in FIG. 3 include a third insulating layer 203 (inorganic insulating layer, which may be referred to as a passivation layer) covering the transistor 21, and the flat layer 40 is provided on a surface of the third insulating layer 203 away from the base substrate 10. In other implementations, an insulating layer (inorganic insulating layer, which may be referred to as a passivation layer) may not be provided on a side of the transistor 21 away from the base substrate 10 in the driving structure layer 20, and the flat layer 40 may directly cover the transistor 21, for example, the flat layer 40 may directly cover the surfaces of the source electrode 213 and the drain electrode 214 of the transistor 21. The pixel driving circuit may have a 3T1C, 4TIC, 5T1C, 5T2C, 6T1C, 7T1C, or 8T1C structure, where T refers to the thin film transistor 21 and C refers to the storage capacitor. Embodiments of the present disclosure do not limit the structure of the pixel driving circuit. In addition, the driving structure layer 20 further includes some signal lines and the like, such as a gate line that supplies a scanning signal to the gate electrode 211 of the transistor 21, and a data line that supplies a data signal to the source electrode 213 or the drain electrode 214 of the transistor 21.

In some exemplary embodiments, as shown in FIG. 3, the light emitting element 51 may be an OLED device. The light emitting element 51 may include a first electrode 511 (such as an anode), an organic light emitting layer 512, and a second electrode (such as a cathode) layer 513 which are sequentially stacked in a direction away from the base substrate 10. The first electrode 511 is connected to the pixel driving circuit. The light emitting element 51 may further include other film layers. For example, any one or more film layers of a hole injection layer, a hole transport layer, and an electron blocking layer may be provided between the first electrode 511 and the organic light emitting layer 512, and any one or more film layers of an electron injection layer, an electron transport layer, and a hole blocking layer may be provided between the second electrode layer 513 and the organic light emitting layer 512.

The first electrode 511 may be made of a transparent conductive material such as indium tin oxide (ITO) or indium zinc oxide (IZO). The second electrode layer 513 may be made of any one or more of Magnesium (Mg), Argentum (Ag), Aluminum (Al), Copper (Cu) and Lithium (Li), or an alloy made of any one or more of the above metals.

In some exemplary embodiments, as shown in FIG. 3, the light emitting element 51 may be a bottom-emission OLED device. The display area 100 may further include a color filter layer 30 located between the flat layer 40 and the driving structure layer 20. The color filter layer 30 includes a plurality of filter units 31, and an orthographic projection of the filter units 31 on the base substrate 10 includes an orthographic projection of the pixel openings 521 on the base substrate 10.

The plurality of filter units 31 may include various types of filter units that transmit light of different colors (the same type of filter unit 31 transmits light of the same color), and each type of filter unit 31 transmits light of a set color. The color of the light transmitted by the filter unit 31 is the color of the light emitted by the corresponding sub-pixel. For example, the plurality of filter units 31 include a plurality of first filter units that transmit light of the first color, a plurality of second filter units that transmit light of the second color, and a plurality of third filter units that transmit light of the third color. The first filter unit is disposed opposite to a pixel opening region of the first sub-pixel, the second filter unit is disposed opposite to a pixel opening region of the second sub-pixel, and the third filter unit is disposed opposite to a pixel opening region of the third sub-pixel.

In some exemplary embodiments, as shown in FIG. 3, the display area may further include an encapsulation structure layer 60 provided on a side of the light emitting structure layer 50 away from the base substrate 10. The encapsulation structure layer 60 may include a first encapsulation layer, a second encapsulation layer, and a third encapsulation layer sequentially stacked in a direction away from the base substrate 10. Materials of the first encapsulation layer and the third encapsulation layer may be inorganic materials, and a material of the second encapsulation layer may be an organic material.

In some exemplary embodiments, as shown in FIG. 3, in the non-light emitting region 102, a surface, which is away from the base substrate 10, of the insulating layer in contact with the flat layer 40 among the plurality of insulating layers is provided with a first groove 81, and the first light extraction structure 71 is provided in the first groove 81. A shape of the first groove 81 and a shape of the first light extraction structure 71 may be the same.

Exemplarily, a refractive index of the first light extraction structure 71 is greater than a refractive index of the flat layer 40, such that the light emitted from the light emitting element 51 is refracted when reaching the interface between the flat layer 40 and the first light extraction structure 71, and the emission angle of the light gets smaller, gathering the light in a direction perpendicular to the base substrate 10 (the emission direction of the light is indicated by dotted lines with arrows in FIG. 3). In this way, a portion of the light that would originally undergo total reflection at the interface between the base substrate 10 and the air and thus cannot be emitted can be extracted, increasing the efficiency of light extraction. Moreover, a large-angle light emitted originally at the interface between the base substrate 10 and the air can be gathered in the direction perpendicular to the base substrate, making a light concentrating and improving light leakage phenomenon.

Exemplarily, a surface of the first light extraction structure 71 facing the base substrate 10 may be a curved surface, such as a hemispherical surface, and a surface of the first light extraction structure 71 away from the base substrate 10 may be a plane surface. The surface of the first light extraction structure 71 facing the base substrate 10 (the interface between the first light extraction structure 71 and the insulating layer) is a hemispherical surface, so that after passing through the center of the hemispherical surface, the light may be emitted from the surface of the first light extraction structure 71 facing the base substrate 10 without changing the emission direction.

Exemplarily, the refractive index of the first light extraction structure 71 may be greater than the refractive index of the flat layer 40, and may be greater than a refractive index of the insulating layer in contact with the flat layer 40 among the plurality of insulating layers.

The flat layer 40 may be made of a resin material, and the refractive index of the flat layer 40 may be about 1.5. The first light extraction structure 71 may be made of an acrylic or epoxy resin material added with zirconia scattering particles.

Exemplarily, the refractive index of the first light extraction structure 71 may be greater than 1.5.

Exemplarily, a plurality of first light extraction structures 71 may be provided, and the plurality of first light extraction structures 71 are provided around the light emitting region 101. Each light emitting region 101 may be surrounded by the plurality of first light extraction structures 71. The light emitted from the light emitting element 51 of the light emitting region 101 may be gathered in a direction perpendicular to the base substrate 10 by the plurality of first light extraction structures 71 surrounding the light emitting region 101. In other implementations, the light emitting region 101 may be surrounded by the first light extraction structure 71 in an annular shape.

In some exemplary embodiments, as shown in FIG. 4, which is a schematic diagram of a cross-sectional structure taken along A-A of FIG. 2 according to some other exemplary embodiments, in the non-light emitting region 102, the first light extraction structure 71 is provided in the insulating layer in contact with the flat layer 40 among the plurality of insulating layers. In the light emitting region 101, a surface, which is away from the base substrate 10, of the insulating layer close to the flat layer 40 among the plurality of insulating layers may be provided with a third groove 83. A third light extraction structure 73 is provided in the third groove 83. The light extraction structure includes a first light extraction structure 71 and a third light extraction structure 73. The third light extraction structure 73 is configured to gather light emitted from the light emitting element 51 in a direction perpendicular to the base substrate 10. One or more of the third light extraction structure 73 may be provided in the light emitting region 101.

In this embodiment, the first light extraction structure 71 is provided in the non-light emitting region 102 and the third light extraction structure 73 is provided in the light emitting region 101. In this way, the emission direction of more emitted light can be changed, so that more light that would originally undergo total reflection at the interface between the base substrate 10 and the air and thus cannot be emitted can be extracted, and the light leakage phenomenon can be improved.

Exemplarily, a shape of the third groove 83 and a shape of the third light extraction structure 73 may be the same. A surface of the third light extraction structure 73 facing the base substrate 10 may be a hemispherical surface, and a surface of the third light extraction structure 73 away from the base substrate 10 may be a plane surface. Thus, since the surface of the third light extraction structure 73 facing the base substrate 10 (the interface between the third light extraction structure 73 and the insulating layer) is a hemispherical surface, after passing through the center of the hemispherical surface, the light may be emitted from the surface of the third light extraction structure 73 facing the base substrate 10 without changing the emission direction.

In some examples of the present embodiment, in the light emitting region 101, the flat layer 40 may be disposed on the surface of the third light extraction structure 73 away from the base substrate 10. A refractive index of the third light extraction structure 73 may be greater than the refractive index of the flat layer 40, such that the light emitted from the light emitting element 51 is refracted when reaching the interface between the flat layer 40 and the third light extraction structure 73, and the emission angle of the light gets smaller, gathering the light in a direction perpendicular to the base substrate 10. The refractive index of the third light extraction structure 73 may also be greater than the refractive index of the insulating layer.

In some examples of the present embodiment, the display area 100 may further include a color filter layer 30 located between the flat layer 40 and the driving structure layer 20. The color filter layer 30 includes a plurality of filter units 31, and the orthographic projection of the filter units 31 on the base substrate 10 includes the orthographic projection of the pixel openings 521 on the base substrate 10. The third light extraction structure 73 may be located on a side of the filter unit 31 facing the base substrate 10.

The filter unit 31 may be disposed on a surface of the third light extraction structure 73 away from the base substrate 10, and the refractive index of the third light extraction structure 73 may be greater than the refractive index of the filter unit 31. In this way, the light emitted from the light emitting element 51 is refracted when reaching the interface between the filter unit 31 and the third light extraction structure 73, and the emission angle of the light gets smaller, gathering the light in a direction perpendicular to the base substrate 10 (the emission direction of the light is indicated by dotted lines with arrows in FIG. 4). The refractive index of the third light extraction structure 73 may also be greater than the refractive index of the insulating layer.

In some examples of the present embodiment, the refractive index of the third light extraction structure 73 may be greater than 1.5.

In some exemplary embodiments, taking the display substrate illustrated in FIG. 3 as an example, a manufacturing process of the display substrate may include the following steps: forming a transistor 21 and a signal line on the base substrate 10; then, forming an inorganic insulating thin film (a third insulating thin film) covering the transistor 21; thereafter, forming the first groove 81 at a position of the third insulating thin film corresponding to the non-light emitting region 102 by a photolithography process, thereby forming the third insulating layer 203; after that, filling the first groove 81 with a material having a higher refractive index (which may be an acrylic or epoxy resin material added with zirconia scattering particles), to form the first light extraction structure 71; thereafter, sequentially manufacturing the color filter layer 30, the flat layer 40, the first electrode 511, the pixel definition layer 52, the organic light emitting layer 512, the second electrode layer 513, and the encapsulation structure layer 60 and other film layers. In the present embodiment, the method of manufacturing the first light extraction structure 71 is simple, and is conductive to the mass production of the display substrate.

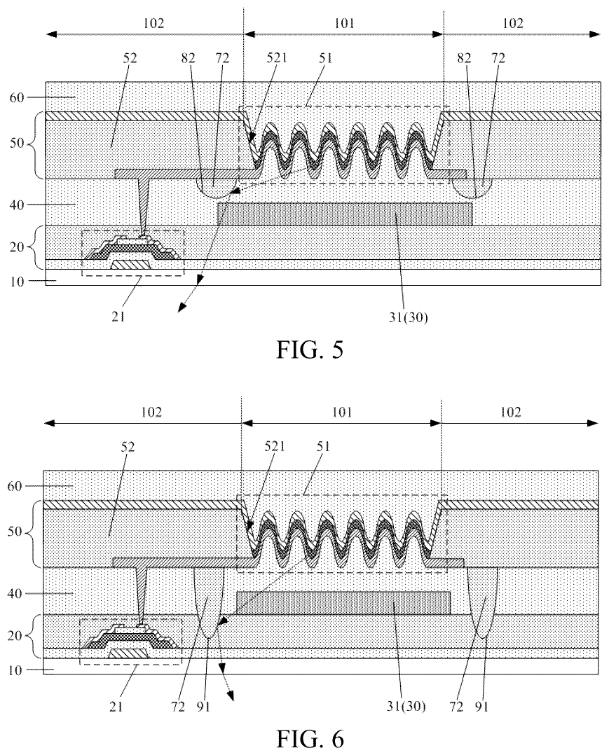

In some exemplary embodiments, as shown in FIG. 5, which is a schematic diagram of a cross-sectional structure taken along A-A of FIG. 2 according to some further exemplary embodiments, the display area 100 includes a driving structure layer 20, a flat layer 40, and a light emitting structure layer 50 sequentially stacked on the base substrate 10 in a direction away from the base substrate 10.

The driving structure layer 20 includes a plurality of pixel driving circuits which includes a plurality of transistors 21. The driving structure layer 20 includes a plurality of conductive structure layers and a plurality of insulating layers in a direction perpendicular to the base substrate 10, and the conductive structure layers and the insulating layers are alternately disposed in a direction perpendicular to the base substrate 10.

The light emitting structure layer 50 includes a plurality of light emitting elements 51, and a pixel definition layer 52 that separates adjacent light emitting elements 51, the pixel definition layer 52 is provided with a plurality of pixel openings 521, and the light emitting elements 51 are provided at the pixel openings 521. A region defined by the pixel openings 521 is a light emitting region 101, and a region other than the light emitting region 101 is a non-light emitting region 102.

In the non-light emitting region 102, the flat layer 40 is provided with a second light extraction structure 72. The light extraction structure includes the second light extraction structure 72, which is configured to gather light emitted from the light emitting element 51 in a direction perpendicular to the base substrate 10.

In some exemplary embodiments, as shown in FIG. 5, the surface of the flat layer 40 away from the base substrate 10 may be provided with a second groove 82, and the second light extraction structure 72 is provided in the second groove 82. A shape of the second groove 82 and a shape of the second light extraction structure 72 may be the same.

Exemplarily, the refractive index of the second light extraction structure 72 may be smaller than the refractive index of the flat layer 40, and the second light extraction structure 72 is configured to cause total reflection of the light emitted by the light emitting element 51 at the interface between the flat layer 40 and the second light extraction structure 72. In this way, when a large-angle emitted light is incident onto the surface of the second light extraction structure 72 from the flat layer 40, the total reflection occurs, the emission angle of the light is changed (the emission angle gets smaller), and the incident angle of the emitted light at the interface between the base substrate 10 and the air can be reduced, so that the light that would originally undergo total reflection at the interface between the base substrate 10 and the air and thus cannot be emitted can be extracted, increasing the efficiency of light extraction (the emission direction of the light is indicated by dotted lines with arrows in FIG. 5). Furthermore, a large-angle light emitted originally at the interface between the base substrate 10 and the air can be gathered in the direction perpendicular to the base substrate, making a light concentrating and improving light leakage phenomenon.

The material of the flat layer 40 may be a resin, the refractive index of the flat layer 40 may be about 1.5, the refractive index of the second light extraction structure 72 may be about 1.4, and the second light extraction structure 72 may be made of a silicone material.

Alternatively, the material of the second light extraction structure 72 may be a high reflectivity material, such as Argentum, Aluminum, or the like. A reflectivity of the second light extraction structure 72 may be 80% or more. In this way, the light incident onto the surface of the second light extraction structure 72 is reflected on the surface of the second light extraction structure 72, the emission angle of the light is changed (the emission angle gets smaller), and the incident angle of the emitted light at the interface between the base substrate 10 and the air can be reduced, so that the light that would originally undergo total reflection at the interface between the base substrate 10 and the air and thus cannot be emitted can be extracted, increasing the efficiency of light extraction.

Exemplarily, the surface of the second light extraction structure 72 facing the base substrate 10 may be a hemispherical surface or a semi-ellipsoid surface (a hemispherical surface in the example of FIG. 5), and the surface of the second light extraction structure 72 away from the base substrate 10 may be a plane surface.

Exemplarily, a plurality of second light extraction structures 72 may be provided, and the plurality of second light extraction structures 72 are provided around the light emitting region 101. In this way, the light emitted from the light emitting element 51 of the light emitting region 101 may be gathered in a direction perpendicular to the base substrate 10 by the plurality of second light extraction structures 72 surrounding the light emitting region 101. In other implementations, the light emitting region may be surrounded by the second light extraction structure in an annular shape.

In some exemplary embodiments, as shown in FIG. 6, which is a schematic diagram of a cross-sectional structure taken along A-A of FIG. 2 according to some further exemplary embodiments, in the non-light emitting region 102, the flat layer 40 and at least one of the insulating layers are provided with a second light extraction structure 72. The light extraction structure includes the second light extraction structure 72 which is configured to gather light emitted by the light emitting element 51 in a direction perpendicular to the base substrate 10.

Exemplarily, the flat layer 40 may be provided with an opening 91 penetrating the flat layer 40, and the second light extraction structure 72 is provided in the opening 91. A shape of the opening 91 and the shape of the second light extraction structure 72 may be the same.

The opening 91 may extend into the insulating layer, i.e. the opening 91 may be disposed in the flat layer 40 and in the at least one of the insulating layers. Accordingly, the second light extraction structure 72 may extend into the insulating layer, and the second light extraction structure 72 may be disposed in the flat layer 40 and in the at least one of the insulating layers. In this way, the dimension of the second light extraction structure 72 in the direction perpendicular to the base substrate 10 can be increased, and more emitted light can be incident onto the surface of the second light extraction structure 72, thereby increasing the light extraction effect.

Exemplarily, the surface of the second light extraction structure 72 facing the light emitting region 101 may be an inclined surface or a curved surface. For example, the surface of the second light extraction structure 72 facing the base substrate 10 may be a hemispherical surface or a semi-ellipsoid surface (a semi-ellipsoid surface in the example of FIG. 6), and the surface of the second light extraction structure 72 away from the base substrate 10 may be a plane surface.

Exemplarily, the refractive index of the second light extraction structure 72 may be smaller than the refractive index of the flat layer 40 and may be smaller than the refractive index of the insulating layer, and the second light extraction structure 72 is configured to cause total reflection of the light emitted by the light emitting element 51 on the surface of the second light extraction structure 72. In this way, when a large-angle emitted light is incident onto the surface of the second light extraction structure 72, the total reflection occurs, the emission angle of the light is changed (the emission angle gets smaller), and the incident angle of the emitted light at the interface between the base substrate 10 and the air can be reduced, so that the light that would originally undergo total reflection at the interface between the base substrate 10 and the air and thus cannot be emitted can be extracted, increasing the efficiency of light extraction (the emission direction of the light is indicated by dotted lines with arrows in FIG. 6).

The material of the flat layer 40 may be a resin, the refractive index of the flat layer 40 may be about 1.5, and the refractive index of the second light extraction structure 72 may be less than 1.5. For example, the refractive index of the second light extraction structure 72 may be about 1.4, and the second light extraction structure 72 may be made of a silicone material.

Alternatively, the material of the second light extraction structure 72 may be a high reflectivity material, such as, Argentum, Aluminum, or the like. The reflectivity of the second light extraction structure 72 may be 80% or more. In this way, the light incident onto the surface of the second light extraction structure 72 is reflected on the surface of the second light extraction structure 72, the emission angle of the light is changed (the emission angle gets smaller), and the incident angle of the emitted light at the interface between the base substrate 10 and the air can be reduced, so that the light that may would originally undergo total reflection at the interface between the base substrate 10 and the air and thus cannot be emitted can be extracted, increasing the efficiency of light extraction.

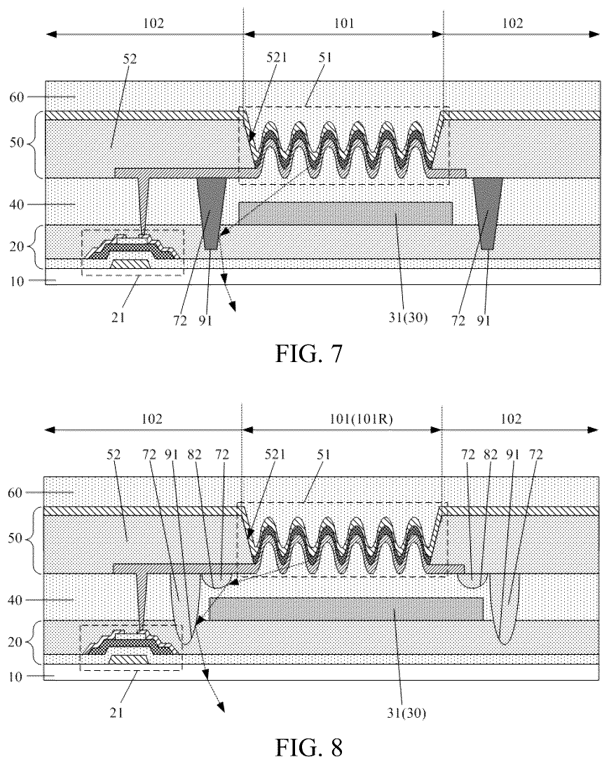

In some exemplary embodiments, as shown in FIG. 7, which is a schematic diagram of a cross-sectional structure taken along A-A of FIG. 2 according to some further exemplary embodiments, in the non-light emitting region 102, the flat layer 40 and at least one of the insulating layers are provided with a second light extraction structure 72. The light extraction structure includes the second light extraction structure 72 which is configured to gather light emitted by the light emitting element 51 in a direction perpendicular to the base substrate 10.

In the non-light emitting region 102, the flat layer 40 may be provided with an opening 91 penetrating the flat layer 40, and the second light extraction structure 72 is provided in the opening 91. The shape of the opening 91 and the shape of the second light extraction structure 72 may be the same.

The opening 91 may extend into the insulating layer, i.e. the opening 91 may be disposed in the flat layer 40 and in at least one of the insulating layers. Accordingly, the second light extraction structure 72 may extend into the insulating layer, and the second light extraction structure 72 may be disposed in the flat layer 40 and in at least one of the insulating layers. In this way, the dimension of the second light extraction structure 72 in the direction perpendicular to the base substrate 10 can be increased, and more emitted light can be incident onto the surface of the second light extraction structure 72, thereby increasing the light extraction effect.

Exemplarily, the surface of the second light extraction structure 72 facing the light emitting region 101 may be an inclined surface or a curved surface (an inclined surface in the example of FIG. 7). For example, the cross-sectional shape of the second light extraction structure 72 in a direction perpendicular to the base substrate 10 may be an inverted trapezoid, and the orthographic projection of the surface of the second light extraction structure 72 away from the base substrate 10 on the base substrate 10 includes the orthographic projection of the surface of the second light extraction structure 72 close to the base substrate 10 on the base substrate 10. In a direction parallel to the base substrate 10, an edge of the surface of the second light extraction structure 72 away from the base substrate 10 is disposed closer to the light emitting region 101 than an edge of the surface of the second light extraction structure 72 close to the base substrate 10. The light extraction effect can be optimized by optimizing an angle of the waist of the inverted trapezoid (the emission direction of the light is indicated by dotted lines with arrows in FIG. 7).

In some exemplary embodiments, as shown in FIG. 8, which is a schematic diagram of a cross-sectional structure taken along A-A of FIG. 2 according to some further exemplary embodiments, at least one light emitting region 101 is a reference light emitting region 101R. In the non-light emitting region 102 surrounding the reference light emitting region 101R, the surface of the flat layer 40 away from the base substrate 10 is provided with a second groove 82. The flat layer 40 is further provided with an opening 91 penetrating the flat layer 40 (the opening 91 can extend to the insulating layer), a second light extraction structure 72 is provided in both the second groove 82 and the opening 91, and the light extraction structure includes the second light extraction structure 72.

The second groove 82 is disposed closer to the reference light emitting region 101R than the opening 91, and the size of the second light extraction structure 72 in the opening 91 is greater than the size of the second light extraction structure 72 in the second groove 82 in a direction perpendicular to the base substrate 10. The light emitted from the light emitting element 51 of the reference light emitting region 101R is first reflected by the second light extraction structure 72 in the second groove 82 and then reflected by the second light extraction structure 72 in the opening 91, and then is emitted from the base substrate 10. In this way, after the light emitted from the light emitting element 51 of the reference light emitting region 101R is reflected a plurality of times, the incident angle of the emitted light at the interface between the base substrate 10 and the air can be reduced, so that the light that would originally undergo total reflection at the interface between the base substrate 10 and the air and thus cannot be emitted can be extracted, increasing the efficiency of light extraction (the emission direction of the light is indicated by dotted lines with arrows in FIG. 8).

Exemplarily, the shape of the opening 91 and the shape of the second light extraction structure 72 in the opening 91 may be the same, and the shape of the second groove 82 and the shape of the second light extraction structure 72 in the second groove 82 may be the same. The surface of the second light extraction structure 72 in the second groove 82 facing the base substrate 10 may be a hemispherical surface, and the surface of the second light extraction structure 72 in the second groove 82 away from the base substrate 10 may be a plane surface. The surface of the second light extraction structure 72 in the opening 91 facing the base substrate 10 may be a semi-ellipsoid surface, and the surface of the second light extraction structure 72 in the opening 91 away from the base substrate 10 may be a plane surface. Alternatively, the cross-sectional shape of the second light extraction structure 72 in the opening 91 in the direction perpendicular to the base substrate 10 may be an inverted trapezoid. The shape of the second light extraction structure 72 in the second groove 82 and the shape of the second light extraction structure 72 in the opening 91 may be the same or different.

Exemplarily, the refractive index of the second light extraction structure 72 in the second groove 82 may be smaller than the refractive index of the flat layer 40. The refractive index of the second light extraction structure 72 in the opening 91 may be smaller than the refractive index of the flat layer 40, and may be smaller than the refractive index of the insulating layer.

In some exemplary embodiments, in the example of FIGS. 5 to 8, in the process of preparing the display substrate, after forming a flat thin film (which may be a resin material), a photolithography process may be used to form a concave-convex lens structure at a position of the flat thin film corresponding to the light emitting region 101, and to form the second groove 82 or/and opening 91 at a position of the flat thin film corresponding to the non-light emitting region 102, thereby forming the flat layer 40. After that, the second groove 82 or/and the opening 91 of the flat layer 40 of the non-light emitting region 102 are filled with a material (which may be a silicone material) with lower refractive index or a high reflectivity material, to form the second light extraction structure 72. Thereafter, film layers such as the first electrode 511, the pixel definition layer 52, the organic light emitting layer 512, the second electrode layer 513, and the encapsulation structure layer 60 are manufacturing sequentially. In the present embodiment, the method of manufacturing the second light extraction structure 72 is simple, and is conductive to the mass production of the display substrate.

An embodiment of the present disclosure further provides a display apparatus, which includes the display substrate according to any one of the previous embodiments. The display apparatus may be any product or component with a display function, such as a mobile phone, a tablet computer, a television, a display, a laptop computer, a digital photo frame, and a navigator.

In the accompanying drawings, a size of a constituent element, and a thickness of a layer or a region are sometimes exaggerated for clarity. Therefore, an implementation of the present disclosure is not necessarily limited to the size, and the shape and size of each component in the drawings do not reflect an actual scale. In addition, the drawings schematically illustrate some examples, and an implementation of the present disclosure is not limited to the shapes or numerical values shown in the drawings.

In the description herein, “parallel” refers to a state in which an angle formed by two straight lines is above −10° and below 10°, and thus includes a state in which the angle is above −5° and below 5°. In addition, “perpendicular” refers to a state in which an angle formed by two straight lines is above 80° and below 100°, and thus includes a state in which the angle is above 85° and below 95°.

In the description herein, orientation or position relationships indicated by the terms “upper”, “lower”, “left”, “right”, “top”, “inside”, “outside”, “axial”, “four corners” and the like are orientation or position relationships shown in the drawings, and are intended to facilitate description of the embodiments of the present disclosure and simplification of the description, but not to indicate or imply that the mentioned structure has a specific orientation or is constructed and operated in a specific orientation, therefore, they should not be understood as limitations on the present disclosure.

In the description herein, unless otherwise specified and defined explicitly, terms “connection”, “fixed connection”, “installation”, and “assembly” should be understood in a broad sense. For example, it may be a fixed connection, a detachable connection, or an integrated connection. The terms “installation”, “connection”, and “fixed connection” may be a direct connection, an indirect connection through an intermediary, or communication inside two elements. For those ordinarily skilled in the art, meanings of the above terms in the embodiments of the present disclosure may be understood according to situations.

1. A display substrate comprising a display area, the display area comprising a driving structure layer, a flat layer, and a light emitting structure layer sequentially stacked on a base substrate in a direction away from the base substrate;
wherein the driving structure layer comprises a plurality of pixel driving circuits, and a pixel driving circuit comprises a plurality of transistors; the driving structure layer comprises a plurality of conductive structure layers and a plurality of insulating layers in a direction perpendicular to the base substrate, and the conductive structure layers and the insulating layers are alternately disposed in the direction perpendicular to the base substrate;
wherein the light emitting structure layer comprises a plurality of light emitting elements, and a pixel definition layer that separates adjacent light emitting elements, the pixel definition layer is provided with a plurality of pixel openings, and the light emitting elements are disposed at the pixel openings; a region defined by the pixel openings is a light emitting region, and a region other than the light emitting region is a non-light emitting region; and
wherein in the non-light emitting region, the flat layer or/and at least one of the insulating layers is provided with a light extraction structure, and the light extraction structure is configured to gather light emitted from the light emitting elements in the direction perpendicular to the base substrate.

2. The display substrate according to claim 1, wherein a surface, which is away from the base substrate, of an insulating layer in contact with the flat layer among the plurality of insulating layers is provided with a first groove, and the light extraction structure comprises a first light extraction structure which is disposed in the first groove.

3. The display substrate according to claim 2, wherein a refractive index of the first light extraction structure is greater than a refractive index of the flat layer.

4. The display substrate according to claim 1, wherein a surface of the flat layer away from the base substrate is provided with a second groove, the light extraction structure comprises a second light extraction structure, and the second light extraction structure is provided in the second groove.

5. The display substrate according to claim 1, wherein the flat layer is provided with an opening penetrating the flat layer and extending into an insulating layer, the light extraction structure comprises a second light extraction structure, and the second light extraction structure is provided in the opening.

6. The display substrate according to claim 4, wherein a refractive index of the second light extraction structure is smaller than a refractive index of the flat layer, and the second light extraction structure is configured to cause total reflection of the light emitted by the light emitting elements at a surface of the second light extraction structure; or a reflectivity of the second light extraction structure is 80% or more.

7. The display substrate according to claim 6, wherein the refractive index of the second light extraction structure is also smaller than a refractive index of an insulating layer.

8. The display substrate according to claim 1, wherein at least one light emitting region is a reference light emitting region, in the non-light emitting region surrounding the reference light emitting region, a surface of the flat layer away from the base substrate is provided with a second groove, the flat layer is further provided with an opening penetrating the flat layer, and the light extraction structure is provided in both the second groove and the opening; and
the second groove is disposed closer to the reference light emitting region than the opening, and a size of the light extraction structure in the opening is greater than a size of the light extraction structure in the second groove in the direction perpendicular to the base substrate; the light emitted from the light emitting elements of the reference light emitting region is first reflected by the light extraction structure in the second groove and then reflected by the light extraction structure in the opening, and then is emitted from the base substrate.

9. The display substrate according to claim 1, wherein a surface of the light extraction structure facing the base substrate is a curved surface and a surface of the light extraction structure away from the base substrate is a plane surface; or a surface of the light extraction structure facing the light emitting region is an inclined surface or a curved surface.

10. The display substrate according to claim 1, wherein a plurality of light extraction structures are provided, and the plurality of light extraction structures are provided around the light emitting region.

11. The display substrate according to claim 1, wherein in the light emitting region, a surface, which is away from the base substrate, of an insulating layer close to the flat layer is provided with a third groove, the light extraction structure comprises a third light extraction structure, the third light extraction structure is provided in the third groove, and the third light extraction structure is configured to gather the light emitted from the light emitting elements in the direction perpendicular to the base substrate.

12. The display substrate according to claim 2, wherein a refractive index of the first light extraction structure is greater than 1.5.

13. The display substrate according to 5claim 4, wherein a refractive index of the second light extraction structure is less than 1.5, or a reflectivity of the second light extraction structure is 80% or more.

14. The display substrate according to claim 1, wherein the display area further comprises a color filter layer located between the flat layer and the driving structure layer, the color filter layer comprises a plurality of filter units, and an orthographic projection of the filter units on the base substrate comprises an orthographic projection of the pixel openings on the base substrate.

15. A display apparatus, comprising the display substrate according to claim 1.

16. The display substrate according to claim 5, wherein a refractive index of the second light extraction structure is smaller than a refractive index of the flat layer, and the second light extraction structure is configured to cause total reflection of the light emitted by the light emitting elements at a surface of the second light extraction structure; or a reflectivity of the second light extraction structure is 80% or more.

17. The display substrate according to claim 5, wherein a refractive index of the second light extraction structure is less than 1.5, or a reflectivity of the second light extraction structure is 80% or more.

18. A display apparatus, comprising the display substrate according to claim 2.

19. A display apparatus, comprising the display substrate according to claim 3.

20. A display apparatus, comprising the display substrate according to claim 4.
